(19) United States
(12) Patent Application Publication
(10) Pub. No.: US 2024/0321708 A1
(43) Pub. Date: Sep. 26, 2024

(54) PACKAGE SUBSTRATE AND SEMICONDUCTOR PACKAGE INCLUDING THE SAME

(71) Applicant: Samsung Electronics Co., Ltd., Suwon-si (KR)

(72) Inventor: Daehun LEE, Suwon-si (KR)

(21) Appl. No.: 18/427,614

(22) Filed: Jan. 30, 2024

(30) Foreign Application Priority Data
Mar. 24, 2023 (KR) 10-2023-0039259
May 26, 2023 (KR) 10-2023-0068618

(51) Int. Cl. H01L 23/498; H01L 23/00

(52) U.S. Cl. CPC H01L 23/49838; H01L 23/49811; H01L 24/16; H01L 24/29; H01L 24/32; H01L 24/73; H01L 2224/16225; H01L 2224/26175; H01L 2224/32225; H01L 2224/73204

(57) ABSTRACT

A semiconductor package includes a semiconductor chip, and a package substrate including a base layer, a plurality of upper bump pads disposed on the base layer, an upper passivation layer disposed on the base layer, the upper passivation layer including a plurality of first openings, and an insulating patch disposed between an outer region of the semiconductor chip and the upper passivation layer, the insulating patch including a plurality of patch openings, and a plurality of bump structures disposed between the upper bump pads and the semiconductor chip, wherein each of the plurality of bump structures is disposed on a corresponding one of the plurality of upper bump pads through a corresponding one of the plurality of first openings of the upper passivation layer and a corresponding one of the plurality of patch openings of the insulating patch.

### CROSS-REFERENCE TO RELATED APPLICATION

This application is based on and claims priority under 35 U.S.C. § 119 to Korean Patent Applications No. 10-2023-0039259, filed on Mar. 24, 2023, and Korean Patent Applications No. 10-2023-0068618, filed on May 26, 2023, in the Korean Intellectual Property Office, the disclosures of which are incorporated by reference herein in their entireties.

### TECHNICAL FIELD

The inventive concept relates to a package substrate and a semiconductor package including the package substrate, and more particularly to a package substrate having an insulation patch.

### DESCRIPTION OF RELATED ART

Due to differences in the coefficients of thermal expansion (CTE) between respective components of a semiconductor package, a warpage phenomenon in which a semiconductor package warps may occur. With trends toward thin, miniature, and lightweight semiconductor chips, damage to the semiconductor chips due to warpage in the semiconductor package may become increasingly common.

### SUMMARY

The inventive concept provides a package substrate and a semiconductor package including the package substrate, and more particularly to a package substrate having an insulation patch.

According to an aspect of the inventive concept, there is provided a semiconductor package including a semiconductor chip, a package substrate including a base layer, a plurality of upper bump pads disposed on the base layer, an upper passivation layer disposed on the base layer, the upper passivation layer including a plurality of first openings, and an insulating patch disposed between an outer region of the semiconductor chip and the upper passivation layer, the insulating patch including a plurality of patch openings, and a plurality of bump structures disposed between the plurality of upper bump pads and the semiconductor chip, wherein each of the plurality of bump structures is disposed on a corresponding one of the plurality of upper bump pads through a corresponding one of the plurality of first openings of the upper passivation layer and a corresponding one of the plurality of patch openings of the insulating patch.

According to another aspect of the inventive concept, there is provided a semiconductor package including a semiconductor chip, a package substrate including a base layer, a plurality of first upper bump pads disposed on the base layer, a plurality of second upper bump pads disposed on the base layer, an upper passivation layer disposed on the base layer, the upper passivation layer including a plurality of first openings, an insulating patch disposed between a corner region of the semiconductor chip and the upper passivation layer, the insulating patch including a plurality of patch openings, and a dam structure disposed on the upper passivation layer, the dam structure at least partially surrounding the semiconductor chip, a plurality of first bump structures disposed between the package substrate and the semiconductor chip, the plurality of first bump structures including a plurality of first solder layers connected to the plurality of first upper bump pads, a plurality of second bump structures disposed between the package substrate and the semiconductor chip, the plurality of second bump structures including a plurality of second solder layers connected to the plurality of second upper bump pads, and an underfill material layer disposed in a gap between the semiconductor chip and the package substrate, the underfill material layer being in contact with the plurality of first bump structures and the plurality of second bump structures, wherein each of the plurality of second bump structures is disposed on a corresponding one of the plurality of second upper bump pads through a corresponding one of the plurality of first openings of the upper passivation layer and a corresponding one of the plurality of patch openings of the insulating patch, and a distance between at least one of the plurality of second solder layers and the base layer is greater than a distance between at least one of the plurality of first solder layers and the top surface of the base layer.

According to another aspect of the inventive concept, there is provided a package substrate including a base layer, a plurality of upper bump pads disposed on the base layer, an upper passivation layer disposed on the base layer, the upper passivation layer including a through hole exposing a center region of the base layer and a plurality of first openings exposing the plurality of upper bump pads, and a plurality of insulating patches on the upper passivation layer, the plurality of insulating patches being disposed apart from each other, wherein each of the plurality of insulating patches includes a plurality of patch openings, aligned with the plurality of first openings of the upper passivation layer.

### BRIEF DESCRIPTION OF THE DRAWINGS

Embodiments of the inventive concept will be more clearly understood from the following detailed description taken in conjunction with the accompanying drawings in which:

FIG. 1 is a plan view of a semiconductor package according to embodiments;

FIG. 2 is a plan view of an insulating patch of a package substrate, according to embodiments;

FIG. 3 is a cross-sectional view of the semiconductor package taken along line X1-X1′ of FIG. 1;

FIG. 4 is a cross-sectional view of the semiconductor package taken along line X2-X2′ of FIG. 1;

FIG. 5 is a plan view of a semiconductor package according to embodiments;

FIG. 6 is a cross-sectional view of the semiconductor package taken along line X3-X3′ of FIG. 5; and

FIG. 7A, FIG. 7B, FIG. 7C, FIG. 7D, and FIG. 7E are cross-sectional views illustrating a method of manufacturing a semiconductor package, according to embodiments.

### DETAILED DESCRIPTION

Hereinafter, embodiments will be described in detail with reference to the accompanying drawings. However, the present disclosure may be implemented in many different forms, and should not be constructed as being limited to embodiments set forth herein. Rather, embodiments are provided so that the present disclosure will be thorough and complete, and will fully convey the concept of the present disclosure to those of ordinary skill in the art. Like reference numerals in the accompanying drawings refer to like elements throughout, and duplicate descriptions thereof are omitted.

As used herein, a vertical direction may be defined as a Z direction, and a lateral direction may be defined as a direction perpendicular to the Z direction. A first lateral direction and a second lateral direction may be defined as directions that intersect with each other. The first lateral direction may be referred to as an X direction, and the second lateral direction may be referred to as a Y direction. The first lateral direction and the second lateral direction may define a plane perpendicular to the vertical direction. A lateral width may refer to a length in the lateral direction, and a vertical length may refer to a length in the vertical direction.

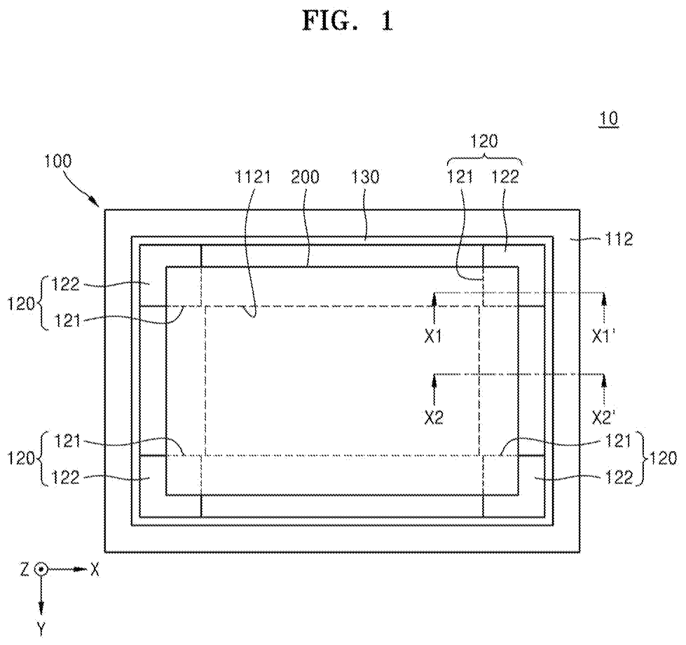

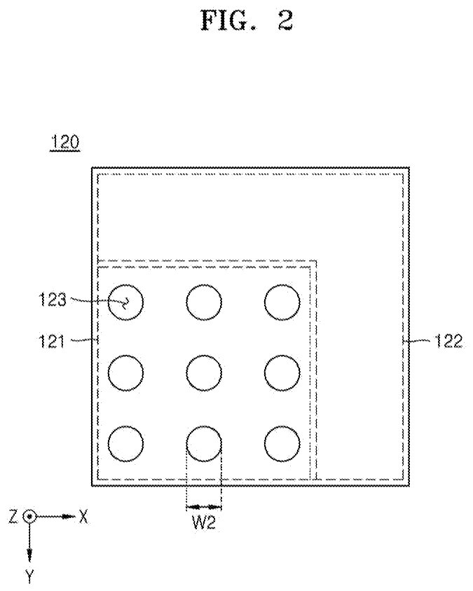

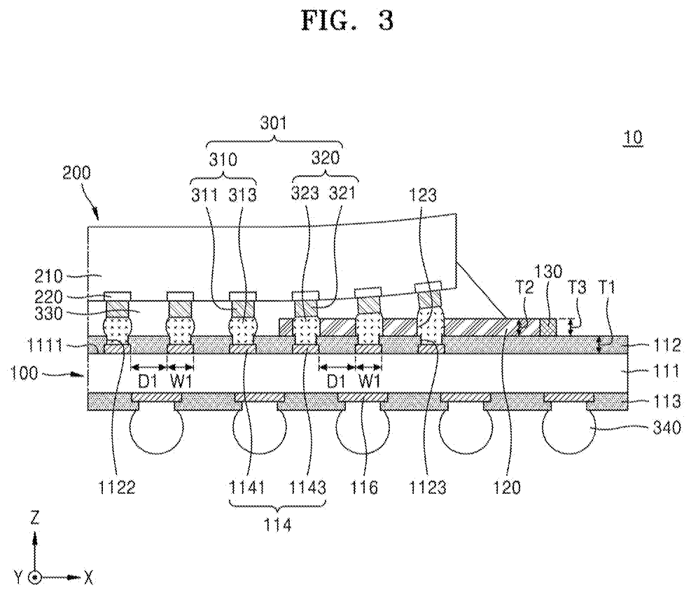

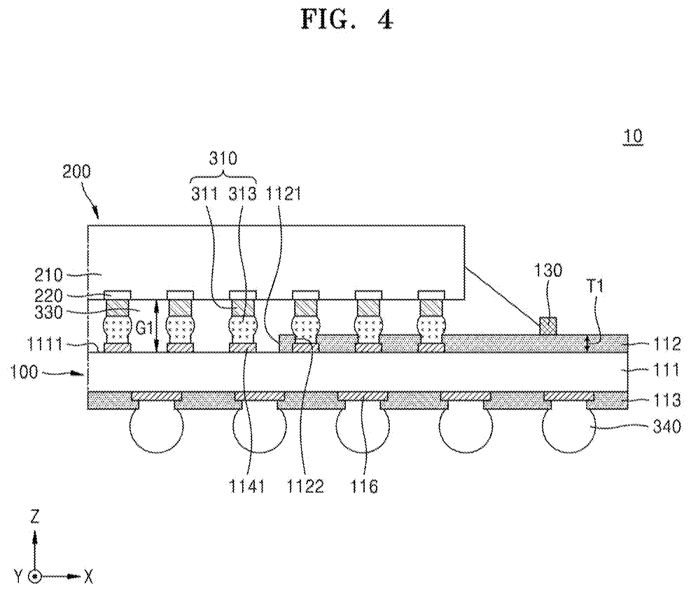

FIG. 1, FIG. 2, FIG. 3, and FIG. 4 are diagrams of a semiconductor package 10 according to embodiments. FIG. 1 is a plan view of the semiconductor package 10 according to embodiments. FIG. 2 is a plan view of an insulating patch 120 of a package substrate 100, according to embodiments. FIG. 3 is a cross-sectional view taken along line X1-X1′ of FIG. 1. FIG. 4 is a cross-sectional view taken along line X2-X2′ of FIG. 1.

Referring to FIG. 1, FIG. 2, FIG. 3, and FIG. 4, the semiconductor package 10 may include the package substrate 100, a semiconductor chip 200 mounted on the package substrate 100, a plurality of bump structures 301 disposed between the package substrate 100 and the semiconductor chip 200, and an underfill material layer 330 disposed in a gap between the package substrate 100 and the semiconductor chip 200. For brevity, the underfill material layer 330 is illustrated in FIG. 1. The underfill material layer 330 may fill the gap between the package substrate 100 and the semiconductor chip 200.

The package substrate 100 may include a base layer 111, a plurality of upper bump pads 114, a plurality of lower bump pads 116, an upper passivation layer 112, a lower passivation layer 113, a plurality of insulating patches 120, and a dam structure 130. The package substrate 100 may include a printed circuit board (PCB) or an interposer substrate. The package substrate 100 may be referred to as a substrate.

The base layer 111 may be substantially flat. For example, the base layer 111 may have a flat plate form or a panel form. The base layer 111 may include a top surface 1111 and a bottom surface, which are opposite to each other. The top surface 1111 and the bottom surface of the base layer 111 may be planar surfaces. The top surface 1111 of the base layer 111 may face the semiconductor chip 200. The base layer 111 may include at least one material selected from a phenol resin, epoxy resin, or polyimide. For example, the base layer 111 may include at least one material selected from prepreg, polyimide, Flame Retardant 4 (FR-4), tetrafunctional epoxy, polyphenylene ether, epoxy/polyphenylene oxide, bismalcimide triazine (BT), thermount, cyanate ester, or liquid crystal polymer.

The plurality of upper bump pads 114 may be disposed on the top surface 1111 of the base layer 111. The plurality of lower bump pads 116 may be on the bottom surface of the base layer 111. Inside the base layer 111, inner connection wirings configured to electrically connect the upper bump pads 114 to the lower bump pads 116 may be provided. The upper bump pads 114 and the lower bump pads 116 may include a metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Rc), beryllium (Be), gallium (Ga), or ruthenium (Ru), or an alloy thereof. The plurality of upper bump pads 114 may include second upper bump pads 1143 overlapping regions in which the insulating patches 120 are located and first upper bump pads 1141 that do not overlap the regions in which the insulating patches 120 are located.

A distance DI between adjacent ones of the upper bump pads 114 may be greater than a lateral width W1 of the upper bump pad 114. For example, the distance DI between the adjacent ones of the upper bump pads 114 may be at least about 130%, at least about 140%, or at least about 150% of the lateral width W1 of the upper bump pad 114. For example, the lateral width W1 of each of the upper bump pads 114 may be between about 50 micrometers (μm) and about 70 μm. For example, the distance DI between adjacent ones of the upper bump pads 114 may be between about 80 μm and about 120 μm.

The upper passivation layer 112 may extend along the top surface 1111 of the base layer 111. The upper passivation layer 112 may be formed to cover at least a portion of the top surface 1111 of the base layer 111 and cover a portion of at least one of the upper bump pads 114. The upper passivation layer 112 may include pad openings configured to expose the upper bump pads 114. The pad openings of the upper passivation layer 112 may include first pad openings 1122 and second pad openings 1123. The first pad openings 1122 may vertically overlap some of the first upper bump pads 1141, and the second pad openings 1123 may vertically overlap the second upper bump pads 1143.

The lower passivation layer 113 may extend along the bottom surface of the base layer 111. The lower passivation layer 113 may be formed to cover the bottom surface of the base layer 111 and cover a portion of each of the lower bump pads 116. The lower passivation layer 113 may include lower openings configured to expose the lower bump pads 116.

The upper passivation layer 112 and the lower passivation layer 113 may include the same material as each other. For example, the upper passivation layer 112 and the lower passivation layer 113 may include solder resist.

In embodiments, a thickness T1 of the upper passivation layer 112 may be between about 6 μm and about 14 μm. A thickness of the lower passivation layer 113 may substantially be equal to or similar to the thickness T1 of the upper passivation layer 112.

The lower bump pads 116 may be connected to external connection terminals 340, respectively. Each of the external connection terminals 340 may be connected to a corresponding one of the lower bump pads 116 through the lower opening of the lower passivation layer 113. The external connection terminals 340 may electrically and physically connect the package substrate 100 to external devices and transmit electric signals between the package substrate 100 and the external devices. The external connection terminals 340 may be formed from a solder ball or a solder bump.

The upper passivation layer 112 may have a through hole 1121. The through hole 1121 of the upper passivation layer 112 may vertically overlap a center region of the semiconductor chip 200. The through hole 1121 of the upper passivation layer 112 may expose a central region of the top surface 1111 of the base layer 111 to the outside of the package substrate 100. The top surface 1111 of the base layer 111 may include the center region not covered by the upper passivation layer 112 and an outer region covered by the upper passivation layer 112. From among the first upper bump pads 1141, the first upper bump pads 1141 on the center region of the top surface 1111 of the base layer 111 may be in contact with the underfill material layer 330 without contacting the upper passivation layer 112.

The plurality of insulating patches 120 may extend along a surface of the upper passivation layer 112. Each of the insulating patches 120 may include an overlap region 121 and a non-overlap region 122. The overlap region 121 may vertically overlap the semiconductor chip 200. The non-overlap region 122 may be disposed outside of a planar extent of the semiconductor chip 200 so as to not vertically overlap the semiconductor chip 200. In a view from above, the non-overlap region 122 of each of the insulating patches 120 may protrude outward from the semiconductor chip 200 and be connected to the dam structure 130. The non-overlap region 122 of each of the insulating patches 120 may include patch openings 123. The patch openings 123 of each of the insulating patches 120 may respectively overlap the second pad openings 1123 of the upper passivation layer 112 in a vertical direction. For example, the patch openings 123 of each of the insulating patches 120 may be respectively aligned to the second pad openings 1123 of the upper passivation layer 112 in the vertical direction. In a view from above, the patch openings 123 aligned with the second pad openings 1123 in the vertical direction may have the same or different diameters. A lateral width W2 of the patch opening 123 of the insulating patch 120 may be equal to or similar to the lateral width W1 of the upper bump pad 114. In a view from above, each of the insulating patches 120 may have a polygonal shape (e.g., a tetragonal shape) or a circular shape.

Each of the plurality of insulating patches 120 may vertically overlap an outer region of the semiconductor chip 200. In embodiments, the plurality of insulating patches 120 may respectively overlap corner regions of the semiconductor chip 200. The outer region of the semiconductor chip 200 may surround a center region of the semiconductor chip 200, and the corner regions of the semiconductor chip 200 may be in the outer region of the semiconductor chip 200. In a view from above, each of the corner regions of the semiconductor chip 200 may be defined as a region including a vertex of a top surface of the semiconductor chip 200. For example, in a view from above, the corner region of the semiconductor chip 200 may be defined as a region that is within a first distance from a corresponding vertex of the top surface of the semiconductor chip 200 in a first lateral direction (X direction) and within a second distance from a corresponding vertex of the top surface of the semiconductor chip 200 in a second lateral direction (Y direction). The first distance may be between about 3% and about 20% of a length of the top surface of the semiconductor chip 200 in the first lateral direction (X direction), and the second distance may be between about 3% and about 20% of a length of the top surface of the semiconductor chip 200 in the second lateral direction (Y direction). For example, the semiconductor chip 200 may have four corner regions, and four insulating patches 120 may respectively overlap the four corner regions of the semiconductor chip 200 in a vertical direction.

In embodiments, a thickness T2 of the insulating patch 120 may be between about 5 μm and about 15 μm. In embodiments, the thickness T2 of the insulating patch 120 may be greater than the thickness T1 of the upper passivation layer 112. A distance between the semiconductor chip 200 and the insulating patch 120 in a vertical direction (Z direction) may be less than a distance between the semiconductor chip 200 and the upper passivation layer 112 in the vertical direction (Z direction).

In embodiments, a length of the non-overlap region 122 of the insulating patch 120 in the first lateral direction (X direction) may be between about 2% and about 5% of the total length of the semiconductor chip 200 in the first lateral direction (X direction).

A material of the plurality of insulating patches 120 may include solder resist, epoxy resin, and/or polyimide. In embodiments, the plurality of insulating patches 120 may include the same material as the upper passivation layer 112. For example, the plurality of insulating patches 120 and the upper passivation layer 112 may include a solder resist. In embodiments, the plurality of insulating patches 120 may include a material different from a material of the upper passivation layer 112. In embodiments, a coefficient of thermal expansion (CTE) of a material of the plurality of insulating patches 120 may be different from a CTE of a material of the upper passivation layer 112. In embodiments, the CTE of the material of the plurality of insulating patches 120 may be greater than the CTE of the material of the upper passivation layer 112. To adjust the CTE of the material of the plurality of insulating patches 120, a type, a size, and/or a density of filler added to the plurality of insulating patches 120 may be adjusted.

The dam structure 130 may be disposed on the upper passivation layer 112. In a view from above, the dam structure 130 may be formed at portions around the semiconductor chip 200 and the plurality of insulating patches 120. For example, the dam structure 130 may have a ring shape surrounding the semiconductor chip 200 and the plurality of insulating patches 120. The dam structure 130 may completely surround the semiconductor chip 200 and the plurality of insulating patches 120. For example, the dam structure 130 may have a tetragonal ring shape surrounding the semiconductor chip 200. In a view from above, the semiconductor chip 200 and the plurality of insulating patches 120 may be disposed in an inner space of the dam structure 130, which may be formed by the ring shape of the dam structure 130. The dam structure 130 may be connected to each of the plurality of insulating patches 120. The dam structure 130 may limit a formation range of the underfill material layer 330 by preventing an under-fill material from flowing to an outside of the dam structure 130 during an under-fill process.

The dam structure 130 may include an insulating material. For example, the dam structure 130 may include solder resist, an epoxy resin, and/or polyimide. In embodiments, the dam structure 130 may include the same material as the upper passivation layer 112 and/or the plurality of insulating patches 120. For example, the material of the dam structure 130, the material of the upper passivation layer 112, and the material of the plurality of insulating patches 120 may include solder resist. In embodiments, the material of the dam structure 130 may be different from the material of the upper passivation layer 112 and/or the material of the plurality of insulating patches 120.

In embodiments, a thickness T3 of the dam structure 130 may greater than or equal to the thickness T2 of the insulating patch 120. In embodiments, a thickness T3 of the dam structure 130 may substantially equal to the thickness T2 of the insulating patch 120. In embodiments, the thickness T3 of the dam structure 130 may be between about 5 μm and about 15 μm. In embodiments, a top surface of the dam structure 130 may be coplanar with a top surface of the insulating patch 120.

The semiconductor chip 200 may be mounted on the package substrate 100 by using a flip-chip process. The semiconductor chip 200 may include a semiconductor substrate 210 and a chip pad 220. The semiconductor substrate 210 may include a top surface and a bottom surface, which are opposite to each other. The bottom surface of the semiconductor substrate 210 may be an active surface of the semiconductor substrate 210, and the top surface of the semiconductor substrate 210 may be an inactive surface of the semiconductor substrate 210. The semiconductor substrate 210 may be formed from a semiconductor wafer. The semiconductor substrate 210 may include, for example, silicon (Si). The semiconductor substrate 210 may include a semiconductor element (e.g., germanium (Ge)) or a compound semiconductor (e.g., silicon carbide (SiC), gallium arsenide (GaAs), indium arsenide (InAs), or indium phosphide (InP)). The semiconductor substrate 210 may include a conductive region, for example, a doped well or a doped structure. A semiconductor device layer including individual devices may be disposed on the active surface of the semiconductor substrate 210. The individual devices may include, for example, transistors. The individual devices may include microelectronic devices, for example, a metal-oxide-semiconductor field effect transistor (MOSFET), a system large-scale integration (LSI), an image sensor (e.g., a CMOS imaging sensor (CIS)), a micro-electro-mechanical system (MEMS), an active device, and/or a passive device. The chip pad 220 may be in a bottom surface of the semiconductor chip 200 and may be electrically connected to the individual devices of the semiconductor device layer.

The semiconductor chip 200 may include a memory chip or a logic chip. The memory chip may be a volatile memory semiconductor device (e.g., at least one of dynamic random access memory (DRAM) or static RAM (SRAM)) or a non-volatile memory semiconductor device (e.g., at least one of phase-change RAM (PRAM), magnetoresistive RAM (MRAM), ferroelectric RAM (FcRAM), or resistive RAM (RRAM)). The logic chip may include a central processing unit (CPU) chip, a graphics processing unit (GPU) chip, an application processor (AP) chip, or an application specific integrated circuit (ASIC) chip.

Although the semiconductor package 10 is illustrated as including a semiconductor chip 200, the semiconductor package 10 may include two or more semiconductor chips 200, which may be electrically connected to each other. In a case that the semiconductor package 10 includes two or more semiconductor chips 200, the semiconductor chips 200 may be stacked in the vertical direction (Z direction) or arranged in parallel on the package substrate 100 in a lateral direction (X direction and/or Y direction). The semiconductor chips 200 may be of the same type or of different types.

The plurality of bump structures 301 may electrically connect the package substrate 100 to the semiconductor chip 200. The plurality of bump structures 301 may include a plurality of first bump structures 310 connected to a plurality of first upper bump pads 1141 and a plurality of second bump structures 320 connected to a plurality of second upper bump pads 1143. The plurality of first bump structures 310 may be disposed apart from the plurality of insulating patches 120, and each of the plurality of second bump structures 320 may be in contact with a corresponding one of the plurality of insulating patches 120.

Each of the first bump structures 310 may include a first solder layer 313 and a first conductive pillar 311. The first conductive pillar 311 may be adhered to a corresponding one of chip pads 220 of the semiconductor chip 200. The first solder layer 313 may extend from the first conductive pillar 311 to a corresponding one of the plurality of first upper bump pads 1141. For example, the first conductive pillars 311 may be disposed between the first solder layers 313 and the chip pads 220 of the semiconductor chip 200. Each of the second bump structures 320 may include a second solder layer 323 and a second conductive pillar 321. The second conductive pillar 321 may be adhered to a corresponding one of the chip pads 220 of the semiconductor chip 200. The second solder layer 323 may extend from the second conductive pillar 321 to a corresponding one of the plurality of second upper bump pads 1143. For example, the second conductive pillars 321 may be disposed between the second solder layers 323 and the chip pads 220 of the semiconductor chip 200. The first conductive pillar 311 and the second conductive pillar 321 may include, for example, copper.

As shown in FIG. 4, individual bump structures of the plurality of first bump structures 310 may be disposed on a center region of the top surface 1111 of the base layer 111 (e.g., a region not covered by the upper passivation layer 112) or on the outer region of the base layer 111. On the outer region of the base layer 111, each of the first bump structures 310 may be in contact with a corresponding one of the plurality of first upper bump pads 1141 through a corresponding one of the first pad openings 1122 of the upper passivation layer 112. On the outer region of the base layer 111, the first solder layer 313 of each of the first bump structure 310 may at least partially fill a corresponding one of the first pad openings 1122 of the upper passivation layer 112.

Each of the second bump structures 320 may be in contact with a corresponding one of the plurality of second upper bump pads 1143 through a corresponding one of the second pad openings 1123 of the upper passivation layer 112 and a corresponding one of the patch openings 123 of the insulating patch 120. For example, the patch openings 123 may be aligned to the second pad openings 1123 and the second upper bump pads 1143. In a view from above, the patch openings 123 aligned with the second pad openings 1123 may have the same or different diameters. The second solder layer 323 of each of the second bump structures 320 may at least partially fill the corresponding one of the second pad openings 1123 of the upper passivation layer 112 and the corresponding one of the patch openings 123 of the insulating patch 120. The second solder layer 323 of each of the second bump structure 320 may be in contact with a sidewall of the insulating patch 120, which may define the corresponding one of the patch openings 123 of the insulating patch 120.

The second solder layer 323 of each of the second bump structures 320 may extend along the sidewall of the insulating patch 120, which may define the patch opening 123 of the insulating patch 120. A shape and dimension of the second solder layer 323 of each of the second bump structures 320 may be determined by a shape and dimension of the patch opening 123 of the insulating patch 120. The shape and size of the second solder layer 323 of each of the second bump structure 320 may be different from a shape and dimension of the first solder layer 313 of each of the first bump structure 310 located outside the insulating patch 120. In addition, a distance between adjacent ones of the second bump structures 320 may substantially be equal to or similar to a distance between adjacent ones of the patch openings 123 of the insulating patch 120. For example, the distance between the adjacent ones of the second bump structures 320 may be between about 80 μm and about 120 μm.

The underfill material layer 330 may be disposed between the semiconductor chip 200 and the package substrate 100. The underfill material layer 330 may be disposed in a gap between the semiconductor chip 200 and the package substrate 100 and may surround each of the plurality of bump structures 301. The underfill material layer 330 may fill the gap between the semiconductor chip 200 and the package substrate 100 and surround each of the plurality of bump structures 301. The underfill material layer 330 may be in contact with the center region of the top surface 1111 of the base layer 111, the upper passivation layer 112, and the plurality of insulating patches 120. A portion of the underfill material layer 330 may extend outward from a side surface of the semiconductor chip 200 and may be in contact with the dam structure 130. The underfill material layer 330 may include, for example, an epoxy resin. In embodiments, the underfill material layer 330 may be formed by using a capillary under-fill process.

A joint gap may be related to a distance Gl between the semiconductor chip 200 and the top surface 1111 of the base layer 111 in the vertical direction (Z direction). For example, the distance Gl between the semiconductor chip 200 and the top surface 1111 of the base layer 111 in the vertical direction (Z direction) may be between about 30 μm and about 50 μm or between about 35 μm and about 45 μm. A size of the joint gap may control a volume of solder included in each bump structure of the plurality of bump structures 301. A volume of solder included in each bump structure of the plurality of bump structures 301 may be related to the joint gap. For example, when the joint gap is small, the volume of solder included in each of the bump structures 301 may be small, thereby reducing production cost.

According to embodiments, the upper passivation layer 112 may have the through hole 1121 exposing the center region of the top surface 1111 of the base layer 111 and the joint gap related to dimensions of the bump structures 301 may be small.

According to embodiments, the insulating patch 120 may provide the patch openings 123. The second bump structures 320 may be disposed in the patch openings 123. The patch openings 123 may be filled by the second bump structures 320, and a shape and size of the second bump structure 320 may be controlled by the insulating patch 120. In a case that the second solder layer 323 of each of the second bump structures 320 is formed from solder having the same volume as the first solder layer 313 of each of the first bump structures 310, a vertical length of each of the second bump structures 320 may be greater than a vertical length of each of the first bump structures 310, and a vertical level (or a top vertical level) of the second solder layer 323 of each of the second bump structures 320 may be higher than a vertical level (or a top vertical level) of the first solder layer 313 of each of the first bump structures 310. A distance between at least one of a plurality of second solder layers 323 and the top surface 1111 of the base layer 111 in the vertical direction (Z direction) may be greater than a distance between at least one of a plurality of first solder layers 313 and the top surface 1111 of the base layer 111 in the vertical direction (Z direction). For example, a height in the vertical direction (Z direction) of the plurality of first solder layers 313 may be less than a height of the plurality of second solder layers 323. When warpage occurs in the semiconductor chip 200, non-wet defects may occur between the second bump structure 320 and the second upper bump pad 1143 near the corner region of the semiconductor chip 200 in a case that a joint gap is relatively large. According to embodiments, a shape and dimension of the second bump structures 320 may be controlled by the insulating patch 120, and non-wet defects caused by warpage in the semiconductor chip 200 may be reduced or prevented in a region between the corner region of the semiconductor chip 200 and the package substrate 100. Accordingly, reliability of connection between the semiconductor chip 200 and the package substrate 100 may improve by using the bump structures 301.

A volume of the upper passivation layer 112 may be related to the through hole 1121. A difference in volume between the upper passivation layer 112 and the lower passivation layer 113 may cause warpage in the semiconductor package 10. When the upper passivation layer 112 has the through hole 1121, a volume of the upper passivation layer 112 may be less than a volume of the lower passivation layer 113. According to embodiments, the plurality of insulating patches 120 may disposed on the base layer 111 and a difference in volume between the upper passivation layer 112 and the lower passivation layer 113 may be reduced, and warpage in the semiconductor package 10 may be reduced or prevented. In embodiments, a warpage control effect using the plurality of insulating patches 120 may be adjusted by adjusting a dimension or volume of the plurality of insulating patches 120. In embodiments, the warpage control effect using the plurality of insulating patches 120 may be enhanced by adjusting the volume and/or the CTE of the plurality of insulating patches 120.

According to embodiments, a distance between the insulating patch 120 and the semiconductor chip 200 may be less than a distance between the upper passivation layer 112 and the semiconductor chip 200 and a distance between the base layer 111 and the semiconductor chip 200, and void defects between the package substrate 100 and the corner region of the semiconductor chip 200 may be reduced or prevented.

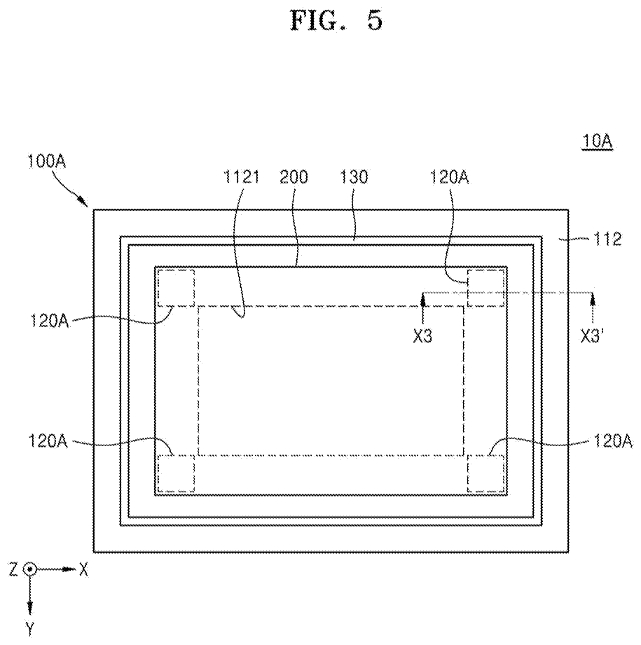

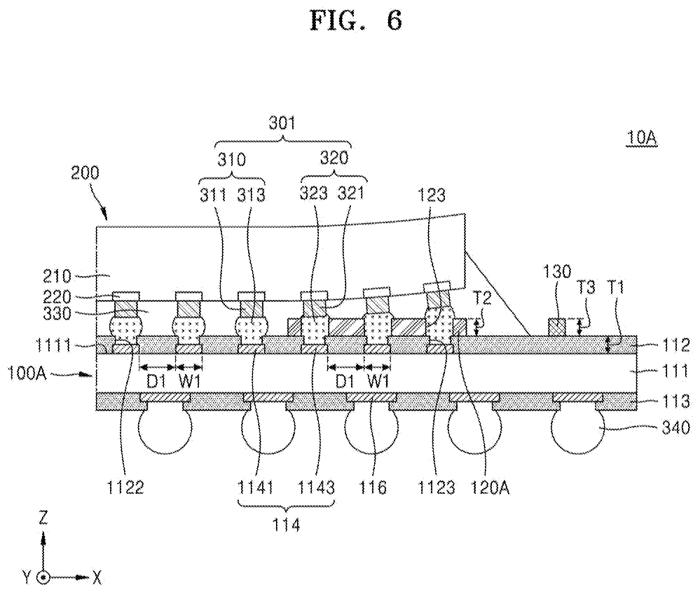

FIG. 5 and FIG. 6 are diagrams of a semiconductor package 10A according to embodiments. FIG. 5 is a plan view of the semiconductor package 10A according to embodiments, and FIG. 6 is a cross-sectional view of the semiconductor package 10A taken along line X3-X3′ of FIG. 5. Hereinafter, descriptions of the semiconductor package 10A shown in FIG. 5 and FIG. 6 focus on differences between the semiconductor package 10A and the semiconductor package 10 described with reference to FIG. 1, FIG. 2, FIG. 3, FIG. 4.

Referring to FIG. 5 and FIG. 6, in the package substrate 100A of the semiconductor package 10A, each of a plurality of insulating patches 120A may be disposed apart from a dam structure 130. Spaces formed by spacing the plurality of insulating patches 120A apart from the dam structure 130 may be at least partially filled by the underfill material layer 330. In embodiments, each of the insulating patches 120A may be entirely covered by a semiconductor chip 200.

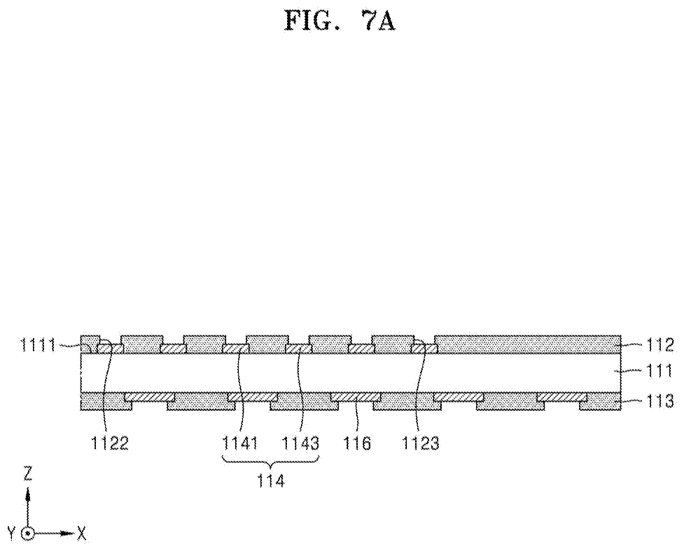

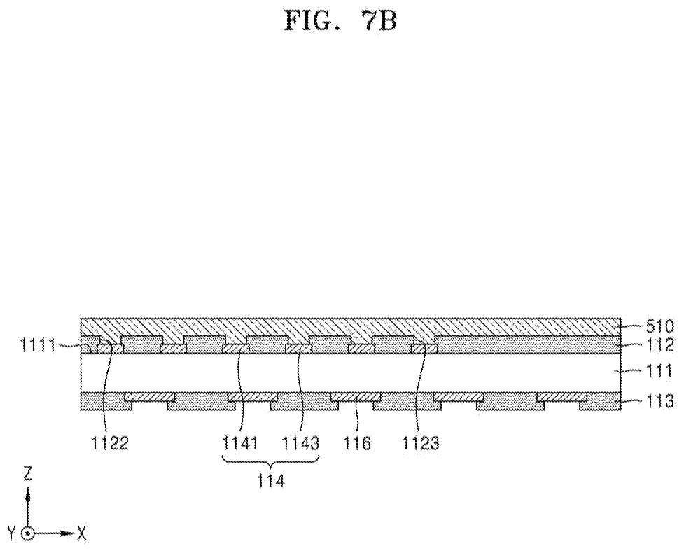

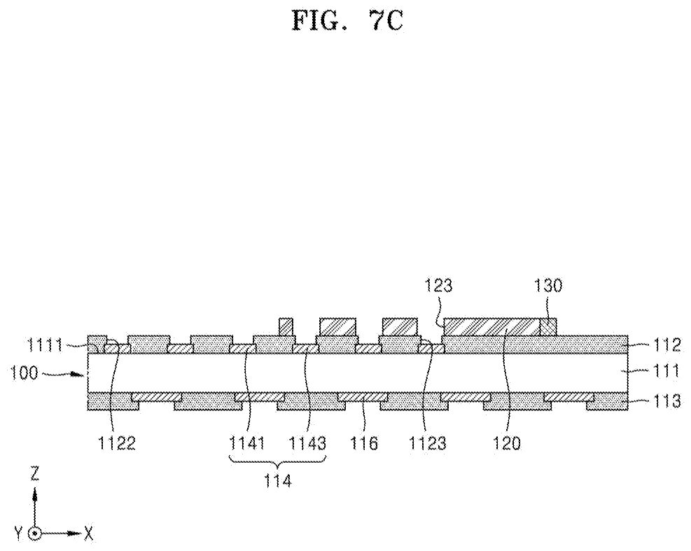

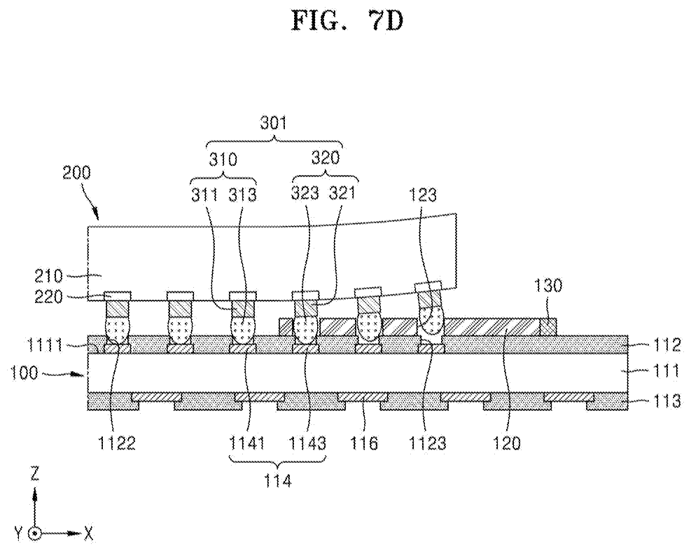

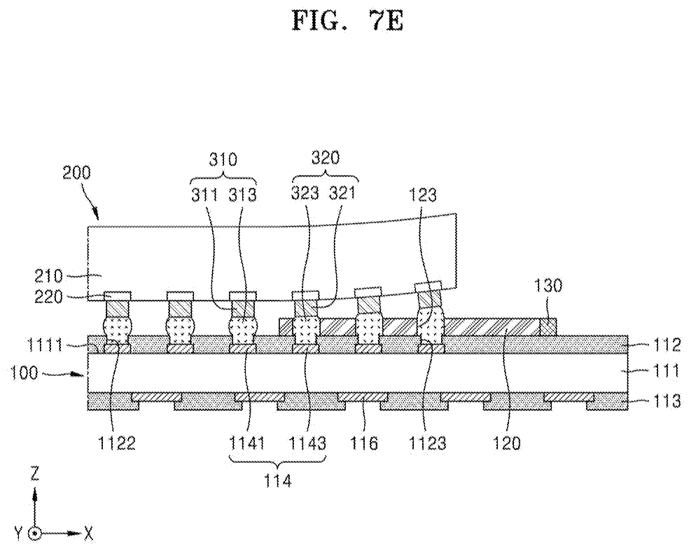

FIG. 7A, FIG. 7B, FIG. 7C, FIG. 7D, and FIG. 7E are cross-sectional views of a method illustrating manufacturing a semiconductor package, according to embodiments. Hereinafter, an example of a method of manufacturing the semiconductor package 10 shown in FIG. 1, FIG. 2, FIG. 3, and FIG. 4 is described with reference to FIG. 7A, FIG. 7B, FIG. 7C, FIG. 7D, and FIG. 7E.

Referring to FIG. 7A, a structure having a base layer 111, upper bump pads 114, lower bump pads 116, an upper passivation layer 112, and a lower passivation layer 113 may be provided. Each of the upper passivation layer 112 and the lower passivation layer 113 may be formed from a solder resist.

Referring to FIG. 7B, a material layer 510 may be disposed on the upper passivation layer 112. The material layer 510 may cover the upper passivation layer 112 and cover the upper bump pads 114, which may be exposed through pad openings of the upper passivation layer 112. The material layer 510 may include, for example, a dry film solder resist (DFSR) or a liquid solder resist material.

Referring to FIG. 7B and FIG. 7C, a patterning process may be performed on the material layer 510, and a plurality of insulating patches 120 and a dam structure 130 may be formed from the material layer 510. The patterning of the material layer 510 may include an exposure process and a developing process. Portions of the material layer 510, which may remain after the exposure process and the developing process, may form the plurality of insulating patches 120 and the dam structure 130. In a case that the plurality of insulating patches 120 and the dam structure 130 are formed by using a same patterning process, the plurality of insulating patches 120 and the dam structure 130 may be formed of a same material. In a cross-sectional view, a lateral width of the patch opening 123 may be equal to or similar to the lateral width of the second upper bump pad 1143. In the cross-sectional view, the patch opening 123 of the insulating patch 120 may have a width greater than or equal to a width of the second pad opening 1123 of the upper passivation layer 112. In embodiments, a package substrate 100 may include the base layer 111, the upper bump pads 114, the lower bump pads 116, the upper passivation layer 112, the lower passivation layer 113, the plurality of insulating patches 120, and the dam structure 130.

Referring to FIG. 7D, a semiconductor chip 200 may be provided and disposed on the package substrate 100. The semiconductor chip 200 may include the plurality of bump structures 301, which may be adhered to the semiconductor chip 200. The plurality of bump structures 301 adhered to the semiconductor chip 200 may be brought into contact with the package substrate 100.

Referring to FIG. 7D and FIG. 7E, a reflow process may be performed, and the plurality of bump structures 301 may be combined with the plurality of upper bump pads 114 of the package substrate 100. A combination of the plurality of bump structures 301 and the plurality of upper bump pads 114 may include forming an electrical connection between the plurality of bump structures 301 and the plurality of upper bump pads 114. During the reflow process, a first solder layer 313 of each of the first bump structures 310 may be melted. Liquid solder formed by melting the first solder layer 313 may fill the first pad opening 1122 of the upper passivation layer 112. Subsequently, as the liquid solder formed by melting the first solder layer 313 hardens, the first solder layer 313 may be combined with the first upper bump pad 1141. During the reflow process, a second solder layer 323 of each of the second bump structures 320 may be melted. Liquid solder formed by melting the second solder layer 323 may fill a second pad opening 1123 of the upper passivation layer 112 and a patch opening 123 of the insulating patch 120. Subsequently, as the liquid solder formed by melting the second solder layer 323 hardens, the second solder layer 323 may be combined with the second upper bump pad 1143. While the second solder layer 323 is being melted and hardened, a shape and dimension of the second solder layer 323 may be determined by the patch opening 123 of the insulating patch 120, and a vertical length of the second solder layer 323 that is reflowed may be greater than a vertical length of the first solder layer 313 that is reflowed.

Referring to FIG. 1 and FIG. 3, an underfill material may be injected into a space between the dam structure 130 and the semiconductor chip 200 and then hardened to form an underfill material layer 330. Thereafter, external connection terminals 340 may be adhered to a bottom side of the package substrate 100.

While the inventive concept has been particularly shown and described with reference to embodiments thereof, it will be understood that various changes in form and details may be made therein without departing from the spirit and scope of the following claims.

What is claimed is:

1. A semiconductor package comprising:
a semiconductor chip; and
a package substrate comprising:
a base layer;
a plurality of upper bump pads disposed on the base layer;
an upper passivation layer disposed on the base layer, the upper passivation layer comprising a plurality of first openings; and
an insulating patch disposed between an outer region of the semiconductor chip and the upper passivation layer, the insulating patch comprising a plurality of patch openings; and
a plurality of bump structures disposed between the plurality of upper bump pads and the semiconductor chip,
wherein each of the plurality of bump structures is disposed on a corresponding one of the plurality of upper bump pads through a corresponding one of the plurality of first openings of the upper passivation layer and a corresponding one of the plurality of patch openings of the insulating patch.

2. The semiconductor package of claim 1, wherein a material of the insulating patch is same as a material of the upper passivation layer.

3. The semiconductor package of claim 1, wherein a material of the insulating patch and a material of the upper passivation layer each comprise a solder resist.

4. The semiconductor package of claim 1, wherein a material of the insulating patch is different from a material of the upper passivation layer.

5. The semiconductor package of claim 1, wherein a coefficient of thermal expansion (CTE) of the insulating patch is different from a CTE of the upper passivation layer.

6. The semiconductor package of claim 1, wherein the insulating patch vertically overlaps a corner region of the semiconductor chip.

7. The semiconductor package of claim 6, wherein
the insulating patch comprises an overlap region vertically overlapping the corner region of the semiconductor chip and a non-overlap region that does not vertically overlap the semiconductor chip, and
the plurality of patch openings are in the overlap region of the insulating patch.

8. The semiconductor package of claim 1, wherein the upper passivation layer exposes a center region of the base layer, and the center region is at least partially surrounded by an outer region covered by the upper passivation layer.

9. The semiconductor package of claim 8, further comprising an underfill material layer disposed in a gap between the semiconductor chip and the package substrate,
wherein the underfill material layer is in contact with the insulating patch, the plurality of bump structures, and the center region of the base layer.

10. The semiconductor package of claim 1, wherein the package substrate further comprises a dam structure disposed on the upper passivation layer, the dam structure at least partially surrounding the semiconductor chip.

11. The semiconductor package of claim 10, wherein a material of the dam structure and a material of the insulating patch are same as each other.

12. The semiconductor package of claim 10, wherein
the dam structure is connected to the insulating patch, and
a top surface of the dam structure is coplanar with a top surface of the insulating patch.

13. The semiconductor package of claim 10, wherein the dam structure is disposed apart from the insulating patch.

14. The semiconductor package of claim 1, wherein each of the plurality of bump structures comprises:
a conductive pillar disposed on the semiconductor chip; and
a solder layer between the conductive pillar and a corresponding one of the plurality of upper bump pads,
wherein the solder layer is in contact with a sidewall of the insulating patch, and
wherein the sidewall of the insulating patch defines a corresponding one of the plurality of patch openings of the insulating patch.

15. A semiconductor package comprising:
a semiconductor chip;
a package substrate comprising:
a base layer;
a plurality of first upper bump pads disposed on the base layer;
a plurality of second upper bump pads disposed on the base layer;
an upper passivation layer disposed on the base layer, the upper passivation layer comprising a plurality of first openings;
an insulating patch disposed between a corner region of the semiconductor chip and the upper passivation layer, the insulating patch comprising a plurality of patch openings; and
a dam structure disposed on the upper passivation layer, the dam structure at least partially surrounding the semiconductor chip;
a plurality of first bump structures disposed between the package substrate and the semiconductor chip, the plurality of first bump structures comprising a plurality of first solder layers connected to the plurality of first upper bump pads;
a plurality of second bump structures disposed between the package substrate and the semiconductor chip, the plurality of second bump structures comprising a plurality of second solder layers connected to the plurality of second upper bump pads; and
an underfill material layer disposed in a gap between the semiconductor chip and the package substrate, the underfill material layer being in contact with the plurality of first bump structures and the plurality of second bump structures,
wherein each of the plurality of second bump structures is disposed on a corresponding one of the plurality of second upper bump pads through a corresponding one of the plurality of first openings of the upper passivation layer and a corresponding one of the plurality of patch openings of the insulating patch, and
a distance between at least one of the plurality of second solder layers and the base layer is greater than a distance between at least one of the plurality of first solder layers and the base layer.

16. The semiconductor package of claim 15, wherein
the upper passivation layer exposes a center region of the base layer, and the center region is at least partially surrounded by an outer region covered by the passivation layer,
the underfill material layer is in direct contact with the center region of the base layer and the insulating patch, and
a distance between the base layer and the semiconductor chip is greater than a distance between the insulating patch and the semiconductor chip.

17. The semiconductor package of claim 15, wherein
a thickness of the upper passivation layer is between about 6 μm and about 14 μm,
a thickness of the insulating patch is between about 10 μm and about 20 μm, and
the upper passivation layer, the insulating patch, and the dam structure comprise a same material as each other.

18. A package substrate comprising:
a base layer;
a plurality of upper bump pads disposed on the base layer;
an upper passivation layer disposed on the base layer, the upper passivation layer comprising a through hole exposing a center region of the base layer and a plurality of first openings exposing the plurality of upper bump pads; and
a plurality of insulating patches on the upper passivation layer, the plurality of insulating patches being disposed apart from each other,
wherein each of the plurality of insulating patches comprises a plurality of patch openings, aligned with the plurality of first openings of the upper passivation layer.

19. The package substrate of claim 18,
further comprising a dam structure disposed on the upper passivation layer, the dam structure at least partially surrounding the plurality of insulating patches,
wherein the upper passivation layer, the plurality of insulating patches, and the dam structure comprise a same material as each other.

20. The package substrate of claim 19, wherein
the plurality of insulating patches are connected to the dam structure, and
top surfaces of the plurality of insulating patches are coplanar with a top surface of the dam structure.
